(19) United States
(12) Patent Application Publication
(10) Pub. No.: US 2015/0295101 A1
(43) Pub. Date: Oct. 15, 2015

(54) METHODS FOR ENHANCING EXCITON DECOUPLING WITH A STATIC ELECTRIC FIELD AND DEVICES THEREOF

(71) Applicant: Nth Tech Corporation, Churchville, NY (US)

(72) Inventor: Michael D. Potter, Churchville, NY (US)

(21) Appl. No.: 14/672,633

(22) Filed: Mar. 30, 2015

Related U.S. Application Data
(60) Provisional application No. 61/978,477, filed on Apr. 11, 2014.

(51) Int. Cl. H01L 31/0216; H01L 31/028; H01L 31/18; H01L 31/0224

(52) U.S. Cl. CPC H01L 31/02167; H01L 31/022425; H01L 31/028; H01L 31/1804

(57) ABSTRACT

An apparatus configured for enhanced exciton decoupling, the apparatus includes an insulator on a surface of the substrate, a positive conductor and a negative conductor. The insulator has a fixed, static charge configured to increase an electric field in an exciton generating region in the substrate adjacent the insulator.

This application claims the benefit of U.S. Provisional Patent Application Ser. No. 61/978,477 filed on Apr. 11, 2014, which is hereby incorporated by reference in its entirety

### FIELD

This technology relates to methods for enhancing exciton decoupling with a static electric field and devices thereof.

### BACKGROUND

Many devices rely on creating an exciton, which is a bound electron-hole pair, which must be decoupled for a specific purpose. A material that acts as an electron donor together with a material that acts as an electron accepter that undergoes energy excitation creates an exciton, i.e. an electron-hole pair that is bound by coulombic force. In order to be useful, this bound exciton must be decoupled. Examples include solar cells of all types, including amorphous silicon, poly crystalline silicon, and single crystal silicon, III-V compounds, hetero junction structures, perovskites, polymers, and other organic photo voltaics (OPV). Other examples include: radiation detectors, such as x-ray detectors; atomic particle detectors, such as alpha and beta particles; nuclear batteries where the decay of a radioactive material, such as tritium, is used to create excitons for long term electrical power generation; and triboelectric generators to name a few.

One way to augment exciton decoupling is to enhance internal electric fields. Unfortunately, previous attempts to augment an internal electric field exhibit poor reliability and decay rather quickly.

For example, radiation induced positive charge in an overlaying insulator of solar cells has had limited success due to the relatively rapid loss of the positive charge. Additionally, any increase in temperature hastens the positive charge loss. Another example includes a solar cell with a transparent Indium-Tin-Oxide (ITO) electrode situated over and spaced apart from the solar cell active region. Unfortunately, this technique adds processing steps, decreases somewhat the solar radiation penetration into the active region, and requires an external applied electrical bias. Still another previous method utilizes a poled ferroelectric material in close proximity to the active region of a solar cell. Unfortunately, ferroelectric materials are inherently insulators and poling tends to decay at moderately elevated temperatures. Additionally, the inherent lack of optical transparency of some ferroelectric materials, added processing steps, and added bulk tend to make this approach impractical.

### SUMMARY

An apparatus configured for enhanced exciton decoupling, the apparatus includes an insulator on a surface of the substrate, a positive conductor and a negative conductor. The insulator has a fixed, static charge configured to increase an electric field in an exciton generating region in the active layer adjacent the insulator.

A method for making an apparatus configured to enhance exciton decoupling, the method forming an insulator on a surface of a substrate. The insulator has a fixed, static charge configured to increase an electric field in an exciton generating region in the active layer adjacent the insulator.

This technology provides a number of advantages including providing more effective methods and devices that enhance exciton decoupling with a static electric field. Additionally, this technology provides longer diffusion lengths and greater carrier lifetimes, which help to reduce unwanted random electron-hole recombination.

### BRIEF DESCRIPTION OF THE DRAWINGS

FIG. 1 is a cross-sectional diagram of an example of a solar cell configured for enhanced exciton decoupling;

FIG. 2 is a cross-sectional diagram of another example of a solar cell with ohmic contacts and configured for enhanced exciton decoupling with ohmic contacts;

FIG. 3 is a cross-sectional diagram of yet another example of a solar cell configured for enhanced exciton decoupling and for reducing unwanted series resistance in substrate;

FIG. 4 is a cross-sectional diagram of yet another example of a solar cell with ohmic contacts and configured for enhanced exciton decoupling and for reducing unwanted series resistance in substrate; and

FIG. 5 is a cross-sectional diagram of yet another example of a solar cell with embedded electrons located on an opposing side from a photovoltaic active material and configured for enhanced exciton decoupling.

### DETAILED DESCRIPTION

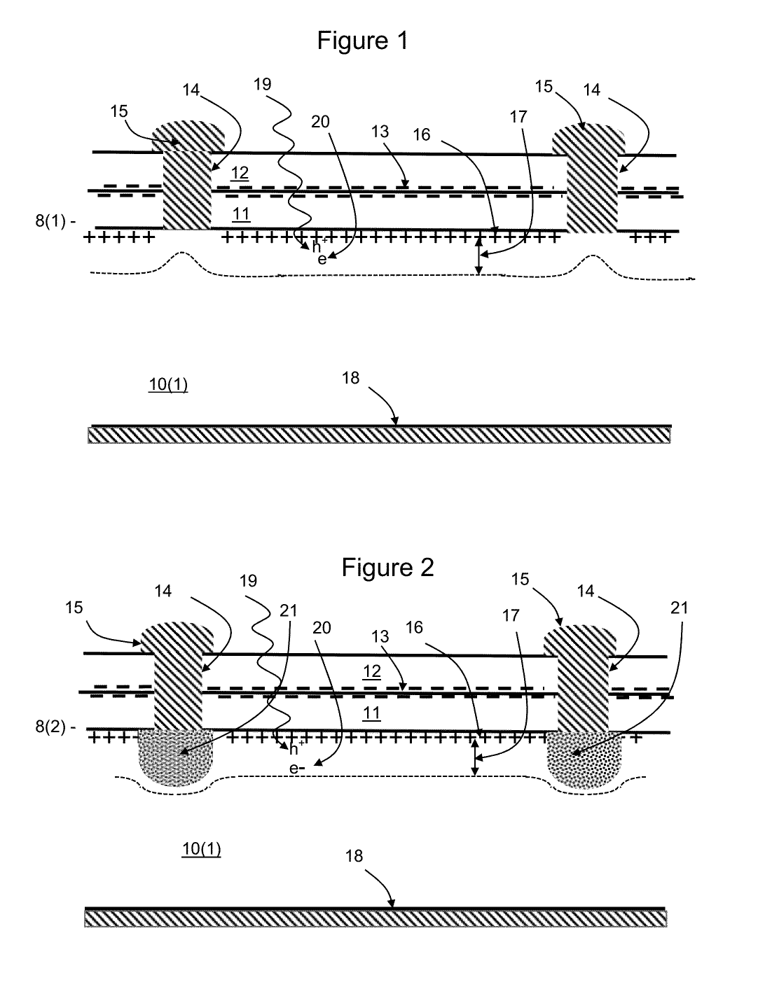

An example of a solar cell 8(1) configured for enhanced exciton decoupling is illustrated in FIG. 1. In this particular example, the solar cell 8(1) includes a lightly doped N-type silicon substrate 10(1), a layer of silicon dioxide 11, a layer of silicon nitride 12, electrons 13, contact holes 14, metal contacts 15, and a contact layer 18, although the solar cell 8(1) can have other types and/or numbers of layers and/or elements in other configurations, such as the solar cells 8(2)-8(4) and 9(1) illustrated in FIGS. 2-5 by way of example only. This technology provides a number of advantages including providing more effective methods and devices that enhance exciton decoupling with a static electric field.

Referring more specifically to FIG. 1, the solar cell 8(1) configured for enhanced exciton decoupling has the layer of silicon dioxide 11 formed on the lightly doped N-type silicon substrate 10(1) and the layer of silicon nitride 12 is formed on the layer of silicon dioxide 11, although the types and/or numbers of other layers can be formed in other manners and/or orders.

A high density of electrons 13 are located at an interface of the composite layer formed by the layer of silicon dioxide 11 and the layer of silicon nitride 12, although the electrons could be located between other types and/or numbers of layers. In this particular example, a high density of electrons 13 can be injected into an interface between the layer of silicon dioxide 11 and the layer of silicon nitride 12 using an approach, such as the one described by way of example only in U.S. Pat. No. 7,287,328 which is again herein incorporate by reference in its entirety. Electrons 13 of up to 3×10¹³ e⁻/cm² embedded at the interface between the layer of silicon dioxide 11 and the layer of silicon nitride 12 can be as high as 3×10¹³ e⁻/cm²to provide the needed static electric field to aid exciton decoupling and thus improving the overall quantum efficiency, although the desired stored electron density can easily be tailored for other types of applications. The retention time of the stored electrons 13 is extremely long and many times longer than the lifetime of a solar cell 8(1) itself or the life times of other structures, such as those in the examples herein. Although injected electrons 13 are illustrated in this particular example, other sources of electron embedded charge at the interface between the layer of silicon dioxide 11 and the layer of silicon nitride 12 could be used, such as polymer electret materials by way of example only.

Additionally, although in this particular example a dissimilar dual insulator structure comprising the layer of silicon dioxide 11 and the layer of silicon nitride 12 is illustrated and described, other types of dissimilar insulator structures may also be utilized for trapping electrons at the interface. By way of example only, these other dissimilar dual insulator structures may include silicon dioxide/aluminum oxide (SiO₂/Al₂O₃), aluminum oxide/silicon nitride (Al₂O₃/Si₃N₄), or dual insulating materials that include various fluorides.

The contact holes 14 are formed at desired locations through the layer of silicon dioxide 11 and the layer of silicon nitride 12. The metal contacts 15 are in the contact holes 14 directly on the lightly doped N-type silicon substrate 10(1) forming a Schottky contact and the positive output terminal for the solar cell 8(1) in this example, although other types and/or numbers of conductive contacts could be used. The contact layer 18 is another conductor deposited on the backside of the substrate 10(1) and becomes the negative output terminal of the solar cell 8(1), although configurations for the contacts can be used.

The operation of the solar cell 8(1) configured for enhanced exciton decoupling will now be described with reference to FIG. 1. The embedded electrons 13 at the interface between the layer of silicon dioxide 11 and the layer of silicon nitride 12 creates an induced inversion layer 16 beneath the layer of silicon dioxide 11 and at the surface of the N-type silicon 10(1). This inversion layer 16 together with the Schottky contact formed by each of the metal contacts 15 each comprise the hole conducting region: positive sign current output. The lightly doped N-type silicon substrate 10(1) provides a wide depletion layer 17, which enhances the probability of exciton generation and decoupling. When an incident photon 19 strikes the solar cell 8(1) an exciton 20 is more easily decoupled by the electric field in the depletion layer 17.

Referring to FIG. 2, a cross-sectional diagram of another example of a solar cell 8(2) configured for enhanced exciton decoupling with ohmic contacts 21 is illustrated. Elements in solar cell 8(2) which are like those in solar cell 8(1) will have like reference numerals. The structure and operation of solar cell 8(2) is that same as solar cell 8(1), except as illustrated and described herein.

In this particular example, each ohmic contact 21 comprises a heavily doped P-type region positioned under and in contact with metal contact 15, although other manners and/or other types of regions for forming ohmic contacts can be used. A variety of different standard integrated circuit fabrication techniques, such as P-type doping by diffusion or P-type ion implant by way of example only, can be used for fabricating the ohmic contacts 21.

The operation of the solar cell 8(2) configured for enhanced exciton decoupling will now be described with reference to FIG. 2. The embedded electrons 13 at the interface between the layer of silicon dioxide 11 and the layer of silicon nitride 12 creates an induced inversion layer 16 beneath the layer of silicon dioxide 11 and at the surface of the N-type silicon 10(1). This inversion layer 16 together with the Schottky contact formed by each of the metal contacts 15 each comprise the hole conducting region: positive sign current output. The lightly doped N-type silicon substrate 10(1) provides a wide depletion layer 17, which enhances the probability of exciton generation and decoupling. Utilizing a P-type contact region 21 eliminates the possible electronic shielding of metal contact 15 and thus ensures electrical continuity between inversion layer 16 and the output terminal 15. When an incident photon 19 strikes the solar cell 8(2) an exciton 20 is more easily decoupled by the electric field in the depletion layer 17 and the overall efficiency is enhanced by an increase in carrier diffusion lengths and carrier lifetimes leading to a reduction in unwanted electron-hole pair recombination.

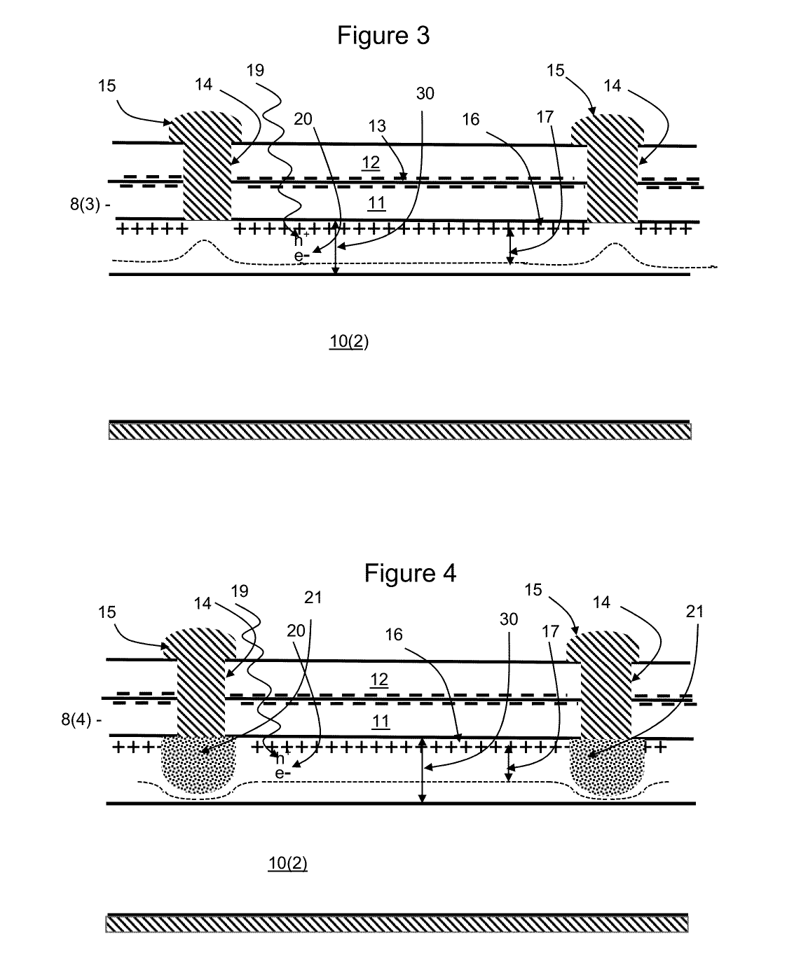

Referring to FIG. 3, a cross-sectional diagram of another example of a solar cell 8(3) configured for enhanced exciton decoupling and for reducing unwanted series resistance in substrate 10(1) is illustrated. Elements in solar cell 8(3) which are like those in solar cell 8(1) will have like reference numerals. The structure and operation of solar cell 8(3) is the same as solar cell 8(1), except as illustrated and described herein.

In this particular example, a high series resistance arising from the previously described lightly doped N-type silicon substrate 10(1) is replaced by a low resistance highly doped N-type silicon substrate 10(2), although other types and/or numbers of base materials could be used. Additionally, in this example a lightly doped N-type silicon epitaxial layer 30 is deposited on the low resistance highly doped N-type silicon substrate 10(2), although other types and/or numbers of layers could be used.

The operation of the solar cell 8(3) configured for enhanced exciton decoupling will now be described with reference to FIG. 3. The embedded electrons 13 at the interface between the layer of silicon dioxide 11 and the layer of silicon nitride 12 creates an induced inversion layer 16 beneath the layer of silicon dioxide 11 and at the surface of the high resistance lightly doped N-type silicon epitaxial layer 30. This inversion layer 16 together with the Schottky contact formed by each of the metal contacts 15 each comprise the hole conducting region: positive sign current output. The lightly doped N-type silicon epitaxial layer 30 deposited on the low resistance highly doped N-type silicon substrate 10(2) provides a wide depletion layer 17, which further enhances the probability of exciton generation and decoupling. When an incident photon 19 strikes the solar cell 8(3) an exciton 20 is more easily decoupled by the electric field in the depletion layer 17.

Referring to FIG. 4, a cross-sectional diagram of another example of a solar cell 8(4) with ohmic contacts and configured for enhanced exciton decoupling and for reducing unwanted series resistance in substrate is illustrated. Elements in solar cell 8(4) which are like those in solar cell 8(1) will have like reference numerals. The structure and operation of solar cell 8(4) is the same as solar cell 8(1), except as illustrated and described herein.

In this particular example, the solar cell 8(4) includes the epitaxial layer 30 and the heavily doped contact regions 21. If it is desired, in order to take advantage of Schottky type contacts formed by the metal contacts 15 and to ensure continuity between the inversion layer 16 and the positive output terminal comprising the metal contacts 15 in this example, instead of the heavily doped P-type contact regions 21 at each of the contact holes 14 can be doped just enough to convert the lightly doped N-type epitaxial layer 30 to lightly doped P-type material, although other configurations can be used. For example, if it is desired, in order to take advantage of Schottky type contacts formed by the metal contacts 15 and to ensure continuity between the inversion layer 16 and the positive output terminal comprising the metal contacts 15, in FIG. 2 instead of the heavily doped P-type contact regions 21 at each of the contact holes 14 can be doped just enough to convert the lightly doped N-type silicon 10(1) to lightly doped P-type material.

The operation of the solar cell 8(4) configured for enhanced exciton decoupling will now be described with reference to FIG. 4. The embedded electrons 13 at the interface between the layer of silicon dioxide 11 and the layer of silicon nitride 12 creates an induced inversion layer 16 beneath the layer of silicon dioxide 11 and at the surface of the high resistance lightly doped N-type silicon epitaxial layer 30. This inversion layer 16 together with the Schottky contact formed by each of the metal contacts 15 each comprise the hole conducting region: positive sign current output. The lightly doped N-type silicon epitaxial layer 30 deposited on the low resistance highly doped N-type silicon substrate 10(2) provides a wide depletion layer 17, which further enhances the probability of exciton generation and decoupling. When an incident photon 19 strikes the solar cell 8(4) an exciton 20 is more easily decoupled by the electric field in the depletion layer 17.

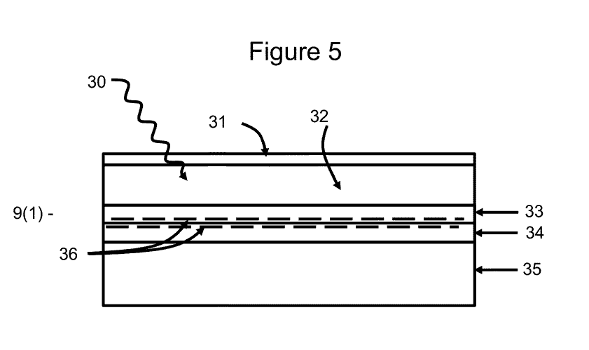

Referring to FIG. 5, an example of a solar cell 9(1) with embedded electrons 13 located on an opposing side from a photovoltaic active material and configured for enhanced exciton decoupling. In this particular embodiment, the solar cell 9(1) has an upper transparent electrode 31, a photovoltaic layer 32, dissimilar insulator layers 33 and 34 where electrons 36 are trapped at the interface of the two layers 33 and 34, and a silicon substrate 35, although the solar cell 9(1) can have other types and/or numbers of layers and/or elements in other configurations. For ease of illustration, the anode and cathode connections for the solar cell 9(1) are not shown.

In this particular example, the solar cell 9(1) configured for enhanced exciton decoupling has a layer of silicon dioxide 34 is formed on the silicon substrate 35 and a layer of silicon nitride 33 is formed on the layer of silicon dioxide 34, although the types and/or numbers of other layers can be formed in other manners and/or orders. Additionally, the photovoltaic layer 32 is formed on the layer of silicon nitride 33 and the upper transparent electrode 31 is formed on the photovoltaic layer 32, although the types and/or numbers of other layers can be formed in other manners and/or orders.

A high density of electrons 36 is located at an interface of the composite layer formed by the layer of silicon dioxide 34 and the layer of silicon nitride 33, although the electrons 36 could be located between other types and/or numbers of insulating layers. By way of example only, for purposes of taking advantage of the relative permittivity differences between insulating layers 33 and 34, aluminum oxide can be used for the layer of silicon nitride 33. In this particular example, a high density of electrons 13 can be injected into an interface between the layer of silicon dioxide 11 and the layer of silicon nitride 12 using an approach, such as the one described by way of example only in U.S. Pat. No. 7,287,328 which is again herein incorporate by reference in its entirety. Additionally, since photovoltaic active layers are typically conductive, the photovoltaic active layer 32 can be utilized as one electrode and the silicon substrate 35 can be utilized as the other electrode for this high electric field injection of electrons 36 into the interface between the dissimilar insulting layers 33 and 34. The electrons 36 are trapped at the interface between the dissimilar insulators 33 and 34 by tunneling into the silicon dioxide layer 34 from the silicon substrate 35 by way of Fowler-Norheim tunneling into the silicon dioxide layer 34 conduction band minimum. The electrons drift in the electric field and thermalize to the minimum energy level at electron traps located at the interface of the dissimilar insulators 33 and 34 and become trapped electrons 36.

The operation of the solar cell 9(1) configured for enhanced exciton decoupling will now be described with reference to FIG. 5. Incident photons 30 will pass through the upper transparent electrode 31 and enter the photovoltaic layer 32. The trapped electrons form an inversion layer in the photovoltaic active layer 32. The operation of the structure is the same as described herein above with reference to FIGS. 1-4 except the insulator layers 33 and 34 and the trapped electrons reside on the opposite side of the incoming incident photon. The example of the structure of FIG. 5 significantly reduces the probability of an incident photon coupling to a trapped electron.

Accordingly, as illustrated and described above this technology can be utilized in a variety of different examples of single crystal silicon based solar cells, although this technology can be utilized with other types of structures, such as organic photovoltaics, radiation detectors, particles detectors, nuclear batteries, triboelectric generators and other forms of solar cells. Additionally, although silicon substrates are shown in the examples illustrated and described herein, other types of substrates may also be used, such as organic substrates.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. An apparatus configured for enhanced exciton decoupling, the apparatus comprising:
a substrate; and
an insulator on a surface of the substrate, the insulator having with a fixed, static charge configured to increase an electric field in an exciton generating region in the substrate adjacent the insulator; and

[symbol]

2. The apparatus as set forth in claim 1 further comprising a positive conductor extending through the insulator and a negative conductor on another surface of the substrate.

3. The apparatus as set forth in claim 1 wherein the insulator comprises at least two dissimilar insulating layers with the fixed, static charge at an interface between the two dissimilar insulating layers.

4. The apparatus as set forth in claim 3 wherein the fixed, static charge is a fixed, static electron charge.

5. The apparatus as set forth in claim 1 wherein the insulator comprises a polymer electret which has the fixed, static charge.

6. The apparatus as set forth in claim 1 wherein the substrate comprises one of a lightly doped N-type substrate or a highly doped N-type substrate coupled with another lightly doped N-type layer.

7. The apparatus as set forth in claim 1 further comprising at least one ohmic contact formed in the substrate and coupled to the positive conductor.

8. The apparatus as set forth in claim 7 wherein the at least one ohmic contact comprises a heavily doped P-type region and the substrate comprises one of a lightly doped N-type substrate or a highly doped N-type substrate coupled with another lightly doped N-type layer.

9. The apparatus as set forth in claim 1 further comprising an epitaxial layer deposited between the substrate and the insulator.

10. The apparatus as set forth in claim 9 wherein the epitaxial layer comprises a lightly doped N-type silicon epitaxial layer and the substrate comprises a more heavily doped N-type silicon substrate.

11. The apparatus as set forth in claim 1 wherein the substrate, the insulator, the positive conductor and the negative conductor comprise one of a solar cell, a nuclear battery, a triboelectric generator, or a radiation detector.

12. The apparatus as set forth in claim 1 wherein the substrate comprises a lightly doped N-type substrate and further comprises at least one region of the lightly doped N-type substrate doped to a lightly doped P-type region which is coupled to the positive conductor.

13. The apparatus as set forth in claim 1 further comprising at least one region of a lightly doped N-type epitaxial layer on the substrate that is doped to a lightly doped P-type region which is coupled to the positive conductor.

14. A method for making an apparatus configured to enhance exciton decoupling, the method comprising:
providing a substrate; and
forming an insulator on a surface of the substrate, the insulator having a fixed, static charge configured to increase an electric field in an exciton generating region in the substrate adjacent the insulator.

15. The method as set forth in claim 14 further comprising a extending a positive conductor through the insulator and a negative conductor on another surface of the substrate.

16. The method as set forth in claim 14 wherein the forming the insulator further comprises providing at least two dissimilar insulating layers with the fixed, static charge at an interface between the two dissimilar insulating layers.

17. The method as set forth in claim 16 wherein the fixed, static charge is a fixed, static electron charge.

18. The method as set forth in claim 14 wherein the forming the insulator further comprises providing a polymer electret which has the fixed, static charge.

19. The method as set forth in claim 14 wherein the substrate comprises one of a lightly doped N-type substrate or a highly doped N-type substrate coupled with another lightly doped N-type layer.

20. The method as set forth in claim 14 further comprising at least one ohmic contact formed in the substrate and coupled to the positive conductor.

21. The method as set forth in claim 20 wherein the at least one ohmic contact comprises a heavily doped P-type region and the substrate comprises one of a lightly doped N-type substrate or a highly doped N-type substrate.

22. The method as set forth in claim 14 wherein the substrate, the insulator, the positive conductor and the negative conductor comprise one of a solar cell, a nuclear battery, a triboelectric generator, or a radiation detector.

23. The method as set forth in claim 14 further comprising forming an epitaxial layer between the substrate and the insulator.

24. The method as set forth in claim 23 wherein the epitaxial layer comprises a lightly doped N-type silicon epitaxial layer and the substrate comprises a more heavily doped N-type silicon substrate.

25. The method as set forth in claim 14 wherein the substrate comprises a lightly doped N-type substrate and further comprises providing at least one region of the lightly doped N-type substrate that is doped to a lightly doped P-type region and is coupled to the positive conductor.

26. The method as set forth in claim 14 further comprising providing at least one region of a lightly doped N-type epitaxial layer on the substrate that is doped to a lightly doped P-type region and is coupled to the positive conductor.
